(19) United States
(12) Patent Application Publication
(10) Pub. No.: US 2025/0318185 A1
(43) Pub. Date: Oct. 9, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Naoki ASANO, Nonoichi Ishikawa (JP)

(21) Appl. No.: 18/885,421

(22) Filed: Sep. 13, 2024

(30) Foreign Application Priority Data
Apr. 8, 2024 (JP) 2024-062096

(51) Int. Cl. H01L 29/78; H01L 29/40; H01L 29/423

(52) U.S. Cl. CPC H10D 30/668; H10D 30/665; H10D 64/117; H10D 64/518

(57) ABSTRACT

A semiconductor device according to an embodiment includes first and second electrode, and a semiconductor layer between the first and second electrode. The semiconductor layer includes a plurality of first trenches and a second trench adjacent to the first trenches. The semiconductor device includes a first gate electrode, a second gate electrode in the second trench and in the second gate electrode a second length on a first trench side is larger than a third length on a opposite side, a first gate insulating layer between the first gate electrode and the semiconductor layer, a second gate insulating layer having a second thickness between the second gate electrode and the semiconductor layer on the first trench side, and a second gate insulating layer having a third thickness between the second gate electrode and the semiconductor layer on the opposite side, the third thickness being larger than the second thickness.

### CROSS-REFERENCE TO RELATED APPLICATION

This application is based upon and claims the benefit of priority from Japanese Patent Application No. 2024-062096, filed on Apr. 8, 2024, the entire contents of which are incorporated herein by reference.

### FIELD

Embodiments described herein relate generally to a semiconductor device.

### BACKGROUND

As an example of a power semiconductor device, there is a vertical trench gate type metal oxide semiconductor field effect transistor (MOSFET) in which a source electrode and a drain electrode are provided so as to interpose a semiconductor layer vertically, and a gate electrode is provided in a trench. In the vertical trench gate type MOSFET, electric field concentration occurs in a trench at the endmost portion among a plurality of trenches disposed in parallel to each other. The electric field concentration causes a problem in reliability of a gate insulating layer provided in the trench at the endmost portion.

### BRIEF DESCRIPTION OF THE DRAWINGS

FIGS. 1A and 1B are schematic views of a semiconductor device according to an embodiment;

FIG. 2 is a schematic cross-sectional view of a part of the semiconductor device according to the embodiment;

FIG. 3 is a schematic top view of a part of the semiconductor device according to the embodiment;

FIG. 4 is an enlarged schematic cross-sectional view of a part of the semiconductor device according to the embodiment;

FIG. 5 is an enlarged schematic cross-sectional view of a part of the semiconductor device according to the embodiment;

FIG. 6 is a view for describing a semiconductor device manufacturing method according to the embodiment;

FIG. 7 is a view for describing the semiconductor device manufacturing method according to the embodiment;

FIG. 8 is a view for describing the semiconductor device manufacturing method according to the embodiment;

FIG. 9 is a view for describing the semiconductor device manufacturing method according to the embodiment;

FIG. 10 is a view for describing the semiconductor device manufacturing method according to the embodiment;

FIG. 11 is a view for describing the semiconductor device manufacturing method according to the embodiment;

FIG. 12 is a view for describing the semiconductor device manufacturing method according to the embodiment;

FIG. 13 is a schematic cross-sectional view of a part of a semiconductor device according to a first comparative embodiment; and

FIG. 14 is a schematic cross-sectional view of a part of a semiconductor device according to a second comparative embodiment.

### DETAILED DESCRIPTION

A semiconductor device according to an embodiment includes: a first electrode; a second electrode; a semiconductor layer provided between the first electrode and the second electrode, having a first face facing the first electrode and a second face facing the second electrode, and including a plurality of first trenches provided on a first face side of the semiconductor layer, extending in a first direction parallel to the first face, and disposed in a repeated pattern in a second direction parallel to the first face and perpendicular to the first direction, a second trench provided on the first face side of the semiconductor layer, extending in the first direction, and disposed adjacent in the second direction to a first trench disposed at an endmost portion in the second direction among the first trenches, a first semiconductor region of a first conductivity type electrically connected to the second electrode, a second semiconductor region of a second conductivity type provided between the first semiconductor region and the first face and provided between two first trenches, and a third semiconductor region of the first conductivity type provided between the second semiconductor region and the first face, provided between two first trenches, and electrically connected to the first electrode; a first gate electrode provided in each of the first trenches and having a first length in a third direction perpendicular to the first direction and the second direction; a first field plate electrode provided in each of the first trenches and provided between the first gate electrode and the second face; a second gate electrode provided in the second trench, and a second length in the third direction of a portion of the second gate electrode on a side facing the first trenches being larger than a third length in the third direction of a portion of the second gate electrode on a side opposite to the first trenches; a second field plate electrode provided in the second trench and provided between the second gate electrode and the second face; a first gate insulating layer provided between the first gate electrode and the semiconductor layer and having a first thickness; a first field plate insulating layer provided between the first field plate electrode and the semiconductor layer; a first inter-electrode insulating layer provided between the first gate electrode and the first field plate electrode; a second gate insulating layer provided between the second gate electrode and the semiconductor layer on the side facing the first trenches and having a second thickness; a third gate insulating layer provided between the second gate electrode and the semiconductor layer on the side opposite to the first trenches and having a third thickness larger than the second thickness; a second field plate insulating layer provided between the second field plate electrode and the semiconductor layer; and a second inter-electrode insulating layer provided between the second gate electrode and the second field plate electrode.

Hereinafter, embodiments of the present disclosure will be described with reference to the drawings. In the following description, the same or similar members and the like are denoted by the same reference numerals, and the description of the members and the like once described is appropriately omitted.

In the present specification, in a case where there are notations of n+ type, n type, and n− type, it means that an n type impurity concentration decreases in the order of n+ type, n type, and n− type. In addition, in a case where there are notations of p+ type, p type, and p− type, it means that a p type impurity concentration decreases in the order of p+ type, p type, and p− type.

An impurity concentration of the semiconductor device can be measured by, for example, secondary ion mass spectrometry (SIMS). A relative level of the impurity concentration of the semiconductor device can also be determined from, for example, a level of a carrier concentration obtained by scanning capacitance microscopy (SCM). Furthermore, a distance such as a width or depth of an impurity region of the semiconductor device can be obtained by, for example, SIMS. Alternatively, the distance such as the width or depth of the impurity region of the semiconductor device can be obtained from, for example, an SCM image.

Qualitative analysis and quantitative analysis of a chemical composition of a member included in the semiconductor device in the present specification can be performed by, for example, SIMS, energy dispersive X-ray spectroscopy (EDX), and Rutherford back-scattering spectrometry (RBS). For example, a scanning electron microscope (SEM) or a transmission electron microscope (TEM) can be used for measuring a thickness of a member included in the semiconductor device, a distance between the members, and the like.

The semiconductor device according to the embodiment includes a first electrode, a second electrode, and a semiconductor layer provided between the first electrode and the second electrode and having a first face facing the first electrode and a second face facing the second electrode. The semiconductor layer includes a plurality of first trenches provided on a side of the semiconductor layer, extending in a first direction parallel to the first face, and disposed in a repeated pattern in a second direction parallel to the first face and perpendicular to the first direction, the side being adjacent to the first face, a second trench provided on the side of the semiconductor layer, extending in the first direction, and disposed adjacent to the first trench disposed at the endmost portion in the second direction among the first trenches in the second direction, the side being adjacent to the first face, a first semiconductor region of a first conductivity type electrically connected to the second electrode, a second semiconductor region of a second conductivity type provided between the first semiconductor region and the first face and provided between two first trenches, and a third semiconductor region of the first conductivity type provided between the second semiconductor region and the first face, provided between two first trenches, and electrically connected to the first electrode. The semiconductor device includes: a first gate electrode provided in the first trench and having a first length in a third direction perpendicular to the first direction and the second direction; a first field plate electrode provided in the first trench and provided between the first gate electrode and the second face; a second gate electrode provided in the second trench and in which a second length of a portion on a side adjacent to the first trench in the third direction is larger than a third length of a portion on a side opposite to the first trench in the third direction; a second field plate electrode provided in the second trench and provided between the second gate electrode and the second face; a first gate insulating layer provided between the first gate electrode and the semiconductor layer and having a first thickness; a first field plate insulating layer provided between the first field plate electrode and the semiconductor layer; a first inter-electrode insulating layer provided between the first gate electrode and the first field plate electrode; a second gate insulating layer provided between the second gate electrode and the semiconductor layer on the side adjacent to the first trench and having a second thickness; a third gate insulating layer provided between the second gate electrode and the semiconductor layer on the side opposite to the first trench and having a third thickness larger than the second thickness; a second field plate insulating layer provided between the second field plate electrode and the semiconductor layer; and a second inter-electrode insulating layer provided between the second gate electrode and the second field plate electrode.

Hereinafter, a case where the first conductivity type is the n type and the second conductivity type is the p type will be described as an example. That is, the case of a metal oxide semiconductor field effect transistor (MOSFET) of an n-channel type using an electron as a carrier will be described as an example.

The semiconductor device according to the embodiment is a MOSFET 100. The MOSFET 100 is a vertical trench gate type MOSFET in which a gate electrode and a field plate electrode are provided in a trench.

The trench in the present specification is a groove-like or recess-like structure of the semiconductor layer itself, and a component other than the semiconductor layer can be provided inside the trench. The trench is a part of the semiconductor layer.

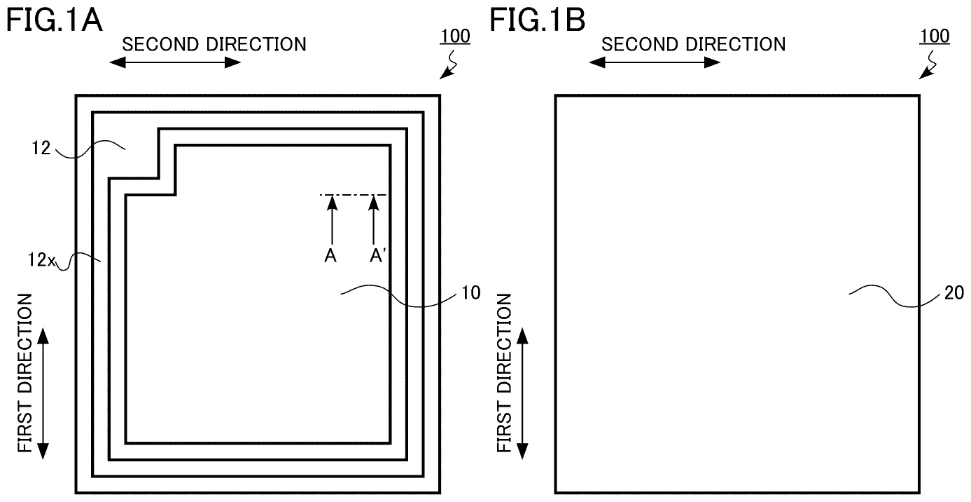

FIGS. 1A and 1B are schematic views of the semiconductor device according to the embodiment. FIG. 1A is a view illustrating a front surface of the MOSFET 100. FIG. 1B is view illustrating a back surface of the MOSFET 100.

As illustrated in FIG. 1A, a source electrode 10, a gate electrode pad 12, and a gate electrode wiring 12x are provided on a front surface side of the MOSFET 100. The gate electrode wiring 12x is connected to the gate electrode pad 12.

As illustrated in FIG. 1B, a drain electrode 20 is provided on a back surface side of the MOSFET 100.

A plurality of transistors are provided under the source electrode 10. The gate electrode pad 12 and the gate electrode wiring 12x are electrically connected to a gate electrode of the transistor. A gate voltage for controlling a switching operation of the transistor is applied to the gate electrode pad 12.

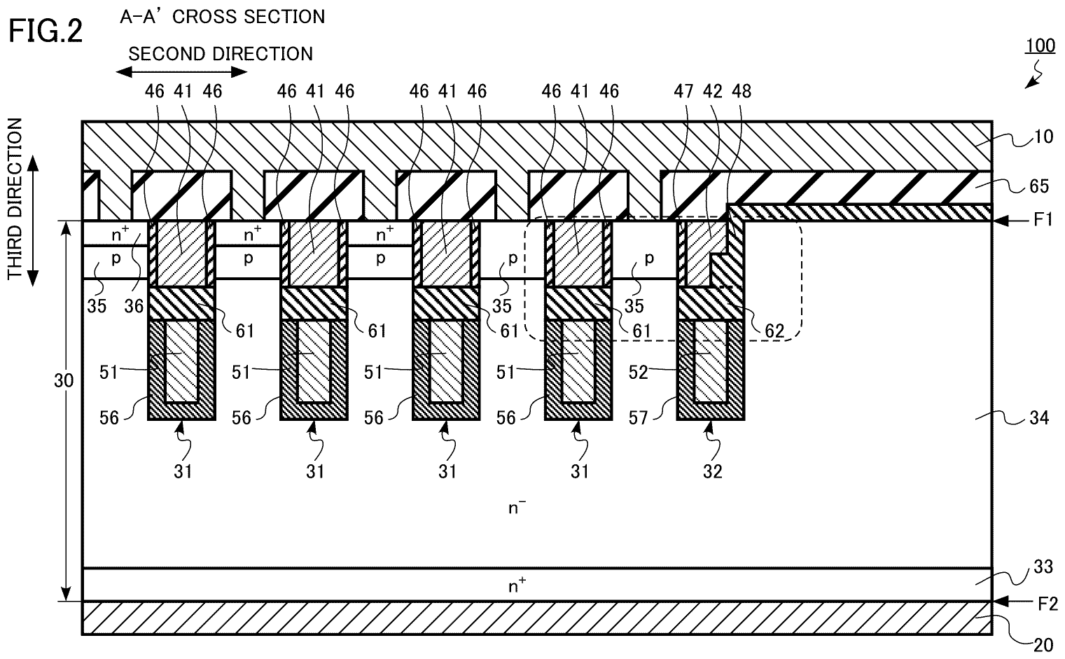

FIG. 2 is a schematic cross-sectional view of a part of the semiconductor device according to the embodiment. FIG. 2 illustrates a cross section taken along line A-A′ in FIG. 1A.

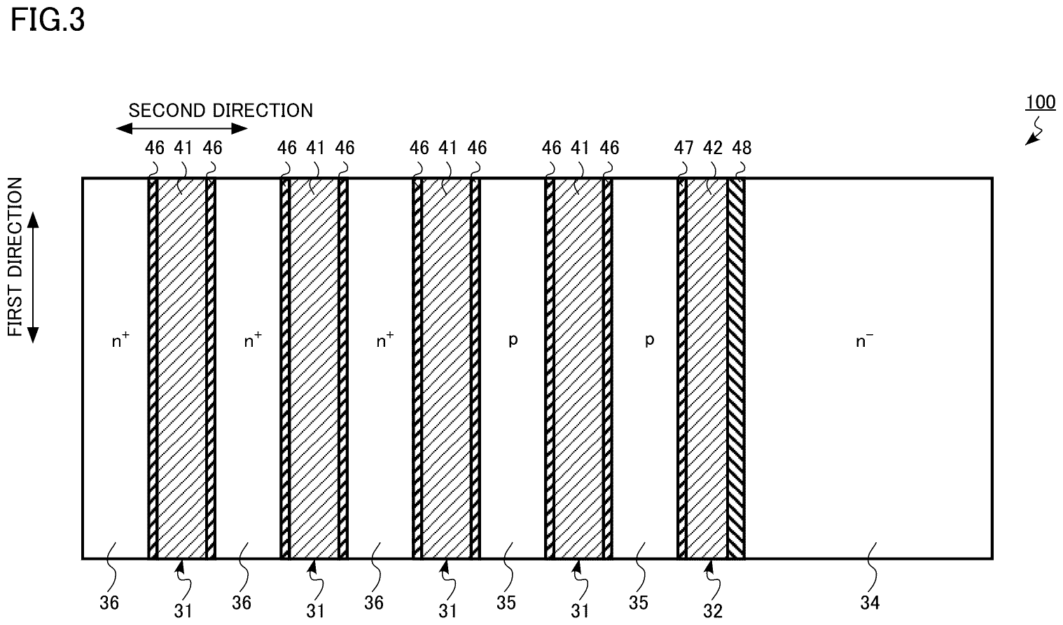

FIG. 3 is a schematic top view of a part of the semiconductor device according to the embodiment. FIG. 3 is a top view of a portion corresponding to FIG. 2. FIG. 3 is a view of a position corresponding to a first face F1 on a semiconductor layer 30. FIG. 3 is a view excluding components on and above the first face F1.

The MOSFET 100 includes a source electrode 10 (first electrode), a drain electrode 20 (second electrode), a semiconductor layer 30, a first gate electrode 41, a second gate electrode 42, a first gate insulating layer 46, a second gate insulating layer 47, a third gate insulating layer 48, a first field plate electrode 51, a second field plate electrode 52, a first field plate insulating layer 56, a second field plate insulating layer 57, a first inter-electrode insulating layer 61, a second inter-electrode insulating layer 62, and an interlayer insulating layer 65.

The semiconductor layer 30 includes a cell trench 31 (first trench), a termination trench 32 (second trench), a drain region 33 of n+ type, a drift region 34 (first semiconductor region) of n− type, a body region 35 (second semiconductor region) of p type, and a source region 36 (third semiconductor region) of n+ type.

The semiconductor layer 30 is provided between the source electrode 10 and the drain electrode 20. The semiconductor layer 30 has the first face (“F1” in FIG. 2) and the second face (“F2” in FIG. 2). The second face F2 faces the first face F1.

The first face F1 faces the source electrode 10. The second face F2 faces the drain electrode 20.

The first direction and the second direction are directions parallel to the first face F1. The second direction is a direction perpendicular to the first direction. A third direction is a direction perpendicular to the first face F1. The third direction is a direction perpendicular to the first direction and the second direction.

Hereinafter, the term “depth” means a depth based on the first face F1. That is, the term “depth” means a distance from the first face F1 in the third direction.

The semiconductor layer 30 is, for example, single crystal silicon (Si). In a case where the semiconductor layer 30 is single crystal silicon, a surface of the semiconductor layer 30 is, for example, a surface inclined at an angle equal to or more than 0° and equal to or less than 8° with respect to a (100) face.

The drain region 33 of n+ type is provided in the semiconductor layer 30. The drain region 33 is in contact with the second face F2. The drain region 33 is in contact with the drain electrode 20. The drain region 33 is electrically connected to the drain electrode 20.

The drain region 33 contains an n type impurity. The n type impurity is, for example, phosphorus (P) or arsenic (As). A concentration of the n type impurity is, for example, equal to or more than 1×10¹⁸ cm⁻³ and equal to or less than 1×10²¹ cm⁻³.

The drift region 34 of n-type is provided in the semiconductor layer 30. The drift region 34 is provided between the drain region 33 and the first face F1. The drift region 34 is provided on the drain region 33. The drift region 34 functions as a current path when the MOSFET 100 is turned on.

The drift region 34 contains an n type impurity. The n type impurity is, for example, phosphorus (P) or arsenic (As). An n type impurity concentration is, for example, equal to or more than 1×10¹⁵ cm⁻³ and equal to or less than 1×10¹⁸ cm⁻³.

A thickness of the drift region 34 in the third direction is, for example, equal to or more than 5 μm and equal to or less than 15 μm.

The body region 35 of p type is provided in the semiconductor layer 30. The body region 35 is provided between the drift region 34 and the first face F1.

The body region 35 is provided between two adjacent cell trenches 31. The body region 35 is provided between the cell trench 31 and the termination trench 32.

The body region 35 is in contact with the source electrode 10, for example. The body region 35 is electrically connected to the source electrode 10, for example.

When the MOSFET 100 is turned on, a channel of an inversion layer is formed in the body region 35 facing the first gate electrode 41.

The body region 35 contains a p type impurity. The p type impurity is, for example, boron (B). A p type impurity concentration is, for example, equal to or more than 1×10¹⁶ cm⁻³ and equal to or less than 1×10¹⁸ cm⁻³.

The source region 36 of n+ type is provided in the semiconductor layer 30. The source region 36 is provided between the body region 35 and the first face F1.

The source region 36 is in contact with the first face F1. The source region 36 is in contact with the source electrode 10. The source region 36 is electrically connected to the source electrode 10.

The source region 36 is provided between two adjacent cell trenches 31.

For example, as illustrated in FIG. 2, the source region 36 is not provided between the cell trench 31 and the termination trench 32. Further, for example, as illustrated in FIG. 2, the source region 36 is not provided between the endmost cell trench 31 and the adjacent cell trench 31. As the source region 36 is not provided at an end portion, for example, discharge of holes to the source electrode 10 during a turn-off operation of the MOSFET 100 is promoted. Therefore, destruction due to avalanche breakdown in the MOSFET 100 is suppressed.

The source region 36 contains an n type impurity. The n type impurity is, for example, phosphorus (P) or arsenic (As). An n type impurity concentration is, for example, equal to or more than 1×10¹⁹ cm⁻³ and equal to or less than 1×10²¹ cm⁻³.

The cell trench 31 is present in the semiconductor layer 30. The cell trench 31 is disposed on a side of the semiconductor layer 30 facing the first face F1. The cell trench 31 is a groove formed in the semiconductor layer 30.

The cell trench 31 extends in the first direction. A plurality of cell trenches 31 are disposed in a repeated pattern in the second direction. The plurality of cell trenches 31 are disposed in a repeated pattern at a constant pitch in the second direction, for example.

The cell trench 31 penetrates through the body region 35 and reaches the drift region 34. A depth of the cell trench 31 is, for example, equal to or more than 1 μm and equal to or less than 5 μm. A width of the cell trench 31 in the second direction is, for example, equal to or more than 0.3 μm and equal to or less than 1 μm.

The termination trench 32 is present in the semiconductor layer 30. The termination trench 32 is disposed on the side of the semiconductor layer 30 facing the first face F1. The termination trench 32 is a groove formed in the semiconductor layer 30.

The termination trench 32 extends in the first direction. The termination trench 32 is adjacent to the cell trench 31 disposed at the endmost portion in the second direction among the plurality of cell trenches 31 in the second direction. The termination trench 32 is provided outside the plurality of cell trenches 31. For example, no trench is provided on a side of the termination trench 32 opposite to the plurality of cell trenches 31.

The termination trench 32 is deeper than the body region 35 and reaches the drift region 34. For example, the body region 35 is not provided outside the termination trench 32. For example, the entire outer side face of the termination trench 32 is in contact with the drift region 34.

A depth of the termination trench 32 is, for example, equal to or more than 1 μm and equal to or less than 5 μm. A width of the termination trench 32 in the second direction is, for example, equal to or more than 0.3 μm and equal to or less than 1 μm.

The width of the termination trench 32 in the second direction is, for example, substantially equal to the width of the cell trench 31 in the second direction. The width of the termination trench 32 in the second direction is, for example, 0.9 times or more and 1.1 times or less the width of the cell trench 31 in the second direction.

The first gate electrode 41 is provided in the cell trench 31. The first gate electrode 41 is electrically connected to the gate electrode wiring 12x and the gate electrode pad 12 by using, for example, a contact structure (not illustrated).

The first gate electrode 41 is a conductor. The first gate electrode 41 is, for example, polycrystalline silicon containing an n type impurity or p type impurity.

The second gate electrode 42 is provided in the termination trench 32. The second gate electrode 42 is electrically connected to the gate electrode wiring 12x and the gate electrode pad 12 by using, for example, the contact structure (not illustrated).

The second gate electrode 42 is a conductor. The second gate electrode 42 is, for example, polycrystalline silicon containing an n type impurity or p type impurity.

The first gate insulating layer 46 is provided between the first gate electrode 41 and the semiconductor layer 30. The first gate insulating layer 46 is provided between the first gate electrode 41 and the body region 35. The first gate insulating layer 46 is provided between the first gate electrode 41 and the drift region 34. The first gate insulating layer 46 is provided between the first gate electrode 41 and the source region 36. The first gate insulating layer 46 is, for example, silicon oxide.

The second gate insulating layer 47 is provided between the second gate electrode 42 and the semiconductor layer 30 on a side of the second gate electrode 42 adjacent to the cell trench 31. The second gate insulating layer 47 is provided between the second gate electrode 42 and the body region 35. The second gate insulating layer 47 is provided between the second gate electrode 42 and the drift region 34. The second gate insulating layer 47 is, for example, silicon oxide.

The third gate insulating layer 48 is provided between the second gate electrode 42 and the semiconductor layer 30 on a side of the second gate electrode 42 opposite to the cell trench 31. The third gate insulating layer 48 is provided between the second gate electrode 42 and the drift region 34. The second gate electrode 42 is provided between the second gate insulating layer 47 and the third gate insulating layer 48 in the second direction. The third gate insulating layer 48 is, for example, silicon oxide.

A thickness of the third gate insulating layer 48 in the second direction is larger than a thickness of the second gate insulating layer 47 in the second direction.

The first field plate electrode 51 is provided in the cell trench 31. The first field plate electrode 51 is provided between the first gate electrode 41 and the second face F2 in the third direction. The first field plate electrode 51 extends in the first direction.

The first field plate electrode 51 has a function of changing electric field distribution in the drift region 34 and improving a breakdown voltage of the MOSFET 100 when the MOSFET 100 is turned off.

The first field plate electrode 51 is electrically connected to the source electrode 10 by using, for example, the contact structure (not illustrated).

The first field plate electrode 51 is a conductor. The first field plate electrode 51 is, for example, polycrystalline silicon containing an n type impurity or p type impurity.

The second field plate electrode 52 is provided in the termination trench 32. The second field plate electrode 52 is provided between the second gate electrode 42 and the second face F2 in the third direction. The second field plate electrode 52 extends in the first direction.

The second field plate electrode 52 has a function of changing the electric field distribution in the drift region 34 and improving the breakdown voltage of the MOSFET 100 when the MOSFET 100 is turned off.

The second field plate electrode 52 is electrically connected to the source electrode 10 by using, for example, the contact structure (not illustrated).

The second field plate electrode 52 is a conductor. The second field plate electrode 52 is, for example, polycrystalline silicon containing an n type impurity or p type impurity.

The first field plate insulating layer 56 is provided between the first field plate electrode 51 and the semiconductor layer 30. The first field plate insulating layer 56 is provided between the first field plate electrode 51 and the drift region 34. The first field plate insulating layer 56 is, for example, silicon oxide.

A thickness of the first field plate insulating layer 56 is, for example, larger than a thickness of the first gate insulating layer 46. The thickness of the first field plate insulating layer 56 is, for example, 3 times or more and 30 times or less the thickness of the first gate insulating layer 46.

The second field plate insulating layer 57 is provided between the second field plate electrode 52 and the semiconductor layer 30. The second field plate insulating layer 57 is provided between the second field plate electrode 52 and the drift region 34. The second field plate insulating layer 57 is, for example, silicon oxide.

A thickness of the second field plate insulating layer 57 is, for example, larger than a thickness of the second gate insulating layer 47. The thickness of the second field plate insulating layer 57 is, for example, 3 times or more and 30 times or less the thickness of the second gate insulating layer 47.

The first inter-electrode insulating layer 61 is provided between the first gate electrode 41 and the first field plate electrode 51. The first inter-electrode insulating layer 61 is, for example, silicon oxide.

A thickness of the first inter-electrode insulating layer 61 is, for example, larger than the thickness of the first gate insulating layer 46 and the thickness of the first field plate insulating layer 56.

The second inter-electrode insulating layer 62 is provided between the second gate electrode 42 and the second field plate electrode 52. The second inter-electrode insulating layer 62 is, for example, silicon oxide.

The second inter-electrode insulating layer 62 may be continuous with the third gate insulating layer 48, for example. The second inter-electrode insulating layer 62 is made of, for example, the same material as that of the third gate insulating layer 48.

A thickness of the second inter-electrode insulating layer 62 is, for example, larger than the thickness of the second gate insulating layer 47 and the thickness of the second field plate insulating layer 57.

The interlayer insulating layer 65 is provided between the first gate electrode 41 and the source electrode 10. The interlayer insulating layer 65 is provided between the second gate electrode 42 and the source electrode 10. The interlayer insulating layer 65 has a function of electrically separating the first gate electrode 41 and the second gate electrode 42 from the source electrode 10.

The interlayer insulating layer 65 is, for example, silicon oxide.

The source electrode 10 is provided on the side of the semiconductor layer 30 facing the first face F1. The source electrode 10 is provided on the first face F1 of the semiconductor layer 30.

The source electrode 10 is electrically connected to the source region 36 and the body region 35. The source electrode 10 is in contact with, for example, the source region 36 and the body region 35.

The source electrode 10 is a region to which a bonding wire is connected, for example, when the MOSFET 100 is mounted.

The source electrode 10 is metal. The source electrode 10 has, for example, a stacked structure of titanium (Ti) and aluminum (Al).

The drain electrode 20 is provided on a side of the semiconductor layer 30 facing the second face F2. The drain electrode 20 is provided on the second face F2 of the semiconductor layer 30. The drain electrode 20 is electrically connected to the drain region 33. The drain electrode 20 is in contact with the drain region 33.

The drain electrode 20 is metal. The drain electrode 20 has, for example, a stacked structure of materials selected from titanium (Ti), aluminum (Al), nickel (Ni), copper (Cu), silver (Ag), and gold (Au).

The gate electrode pad 12 is provided on the side of the semiconductor layer 30 facing the first face F1. The gate electrode pad 12 is provided on the first face F1 of the semiconductor layer 30. As illustrated in FIG. 1A, for example, the gate electrode pad 12 and the gate electrode wiring 12x surround the source electrode 10.

The gate electrode pad 12 is electrically connected to the first gate electrode 41 and the second gate electrode 42. The gate electrode pad 12 is, for example, a region to which a bonding wire is connected when the MOSFET 100 is mounted.

The gate electrode pad 12 is metal. The gate electrode pad 12 has, for example, a stacked structure of titanium (Ti) and aluminum (Al). A material of the gate electrode pad 12 is, for example, the same as a material of the source electrode 10.

The gate electrode wiring 12x is electrically connected to the first gate electrode 41 and the second gate electrode 42. The gate electrode pad 12 is electrically connected to the first gate electrode 41 and the second gate electrode 42 by using the gate electrode wiring 12x.

The gate electrode wiring 12x is metal. The gate electrode wiring 12x has, for example, a stacked structure of titanium (Ti) and aluminum (Al). A material of the gate electrode wiring 12x is, for example, the same as the material of the source electrode 10 and the material of the gate electrode pad 12.

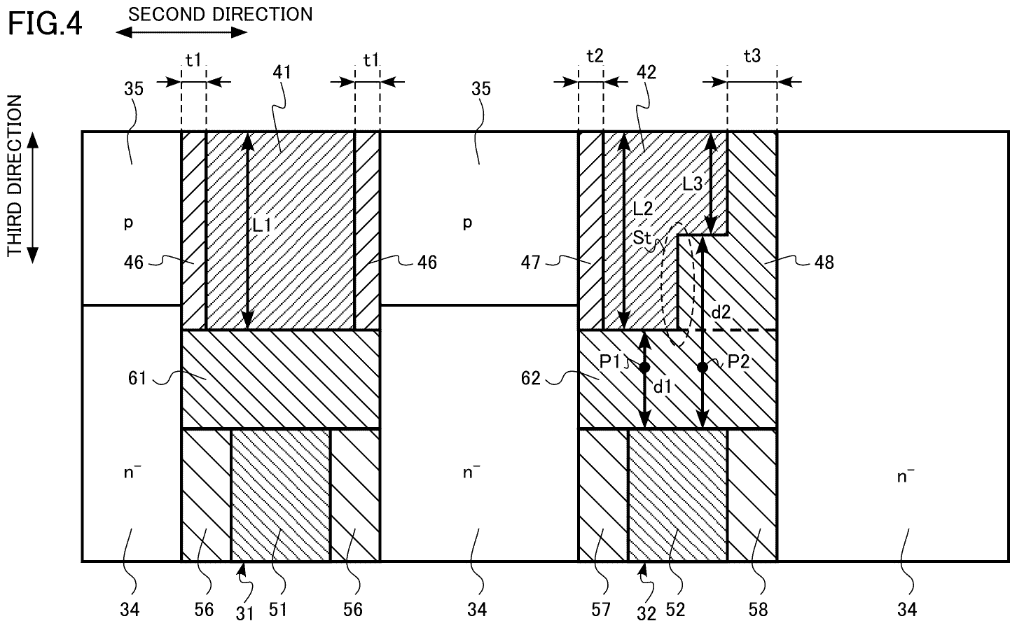

FIG. 4 is an enlarged schematic cross-sectional view of a part of the semiconductor device according to the embodiment. FIG. 4 is an enlarged view of a portion surrounded by a dotted line in FIG. 2. In FIG. 4, illustration of the source electrode 10 and the interlayer insulating layer 65 is omitted.

The first gate electrode 41 has a first length (L1 in FIG. 4) in the third direction. A second length (L2 in FIG. 4) of a first portion of the second gate electrode 42 on the side adjacent to the cell trench 31 in the third direction is larger than a third length (L3 in FIG. 4) of a second portion of the second gate electrode 42 on the side opposite to the cell trench 31 in the third direction.

The second gate electrode 42 includes the first portion on the side adjacent to the cell trench 31 and the second portion on the side opposite to the cell trench 31. The second length L2 of the first portion in the third direction is larger than the third length L3 of the second portion in the third direction.

The second length L2 is, for example, 1.2 times or more and 3 times or less the third length L3.

The second length L2 is, for example, substantially the same as the first length L1. The second length L2 is, for example, 0.9 times or more and 1.1 times or less the first length L1.

A face of the second gate electrode 42 on a side facing the second face F2 has a step St (a region surrounded by a dotted line in FIG. 4). A lower face of the second gate electrode 42 has the step St.

The first gate insulating layer 46 has a first thickness (t1 in FIG. 4) in the second direction. The second gate insulating layer 47 has a second thickness (t2 in FIG. 4) in the second direction. The third gate insulating layer 48 has a third thickness (t3 in FIG. 4) in the second direction.

The first thickness t1 of the first gate insulating layer 46 is, for example, a thickness of the thinnest portion of the first gate insulating layer 46. The second thickness t2 of the second gate insulating layer 47 is, for example, a thickness of the thinnest portion of the second gate insulating layer 47. The third thickness t3 of the third gate insulating layer 48 is, for example, a thickness of the thinnest portion of the third gate insulating layer 48.

The third thickness t3 is larger than the second thickness t2. The third thickness t3 is, for example, 1.5 times or more and 5 times or less the second thickness t2.

The second thickness t2 is, for example, substantially the same as the first thickness t1. The second thickness t2 is, for example, 0.9 times or more and 1.1 times or less the first thickness t1.

The first thickness t1 is, for example, equal to or more than 30 nm and equal to or less than 100 nm. The second thickness t2 is, for example, equal to or more than 30 nm and equal to or less than 100 nm. The third thickness t3 is, for example, equal to or more than 45 nm and equal to or less than 500 nm.

At a first position (P1 in FIG. 4) in the second inter-electrode insulating layer 62, a distance between the second gate electrode 42 and the second field plate electrode 52 in the third direction is a first distance (d1 in FIG. 4). At a second position (P2 in FIG. 4) in the second inter-electrode insulating layer 62, a distance between the second gate electrode 42 and the second field plate electrode 52 in the third direction is a second distance (d2 in FIG. 4).

The first position P1 is closer to the cell trench 31 than the second position P2 in the second direction. In other words, the second position P2 is farther from the cell trench 31 than the first position P1 in the second direction.

The first distance d1 is smaller than the second distance d2. In other words, the second distance d2 is larger than the first distance d1. The second distance d2 is, for example, 1.2 times or more and 2 times or less the first distance d1.

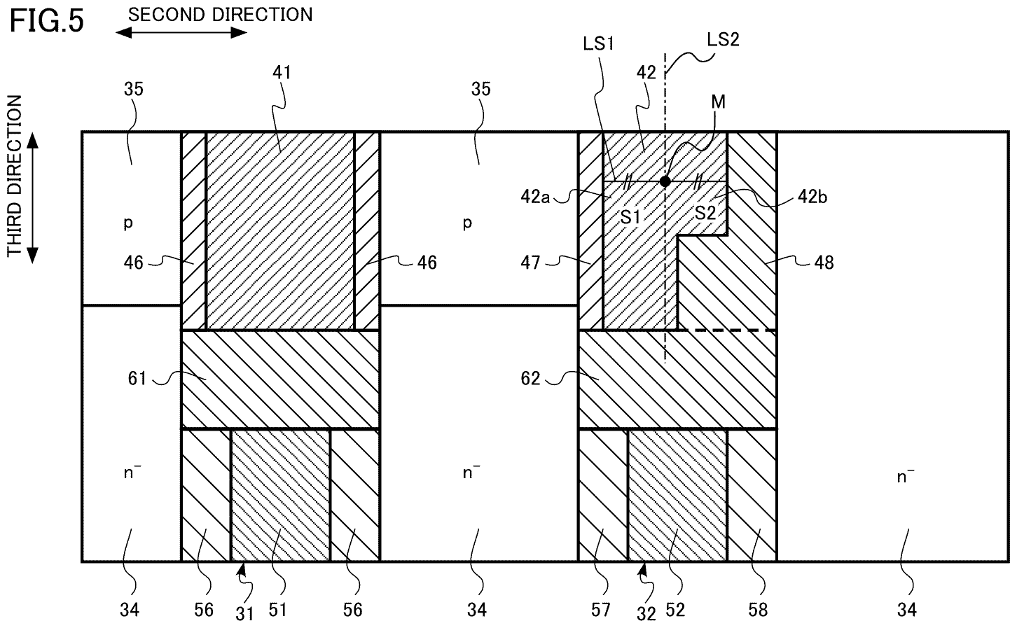

FIG. 5 is an enlarged schematic cross-sectional view of a part of the semiconductor device according to the embodiment. FIG. 5 is an enlarged view of a portion surrounded by a dotted line in FIG. 2. In FIG. 5, illustration of the source electrode 10 and the interlayer insulating layer 65 is omitted. FIG. 5 is a view illustrating the same portion as FIG. 4.

FIG. 5 illustrates a cross section parallel to the second direction and the third direction. In the cross section parallel to the second direction and the third direction, in a case where the second direction is defined as a left-right direction, a shape of the second gate electrode 42 is asymmetrical in the left-right direction.

In the cross section parallel to the second direction and the third direction, a line segment passing through a position where the second gate electrode 42 has the maximum width in the second direction and drawn in the second direction in the second gate electrode 42 is defined as a first line segment (LS1 in FIG. 5). The second gate electrode 42 is virtually divided into left and right parts by a second line segment (LS2 in FIG. 5) passing through a midpoint (M in FIG. 5) of the first line segment LS1 and extending in the third direction. The second gate electrode 42 is divided into a first region 42a on the side adjacent to the cell trench 31 and a second region 42b on the side opposite to the cell trench 31 with the second line segment LS2 interposed between the first region 42a and the second region 42b. In this case, a first area (S1 in FIG. 5) of the first region 42a is larger than a second area (S2 in FIG. 5) of the second region 42b.

The first area S1 of the first region 42a is, for example, 1.2 times or more and 5 times or less the second area of the second region 42b.

Next, an example of a semiconductor device manufacturing method according to the embodiment will be described.

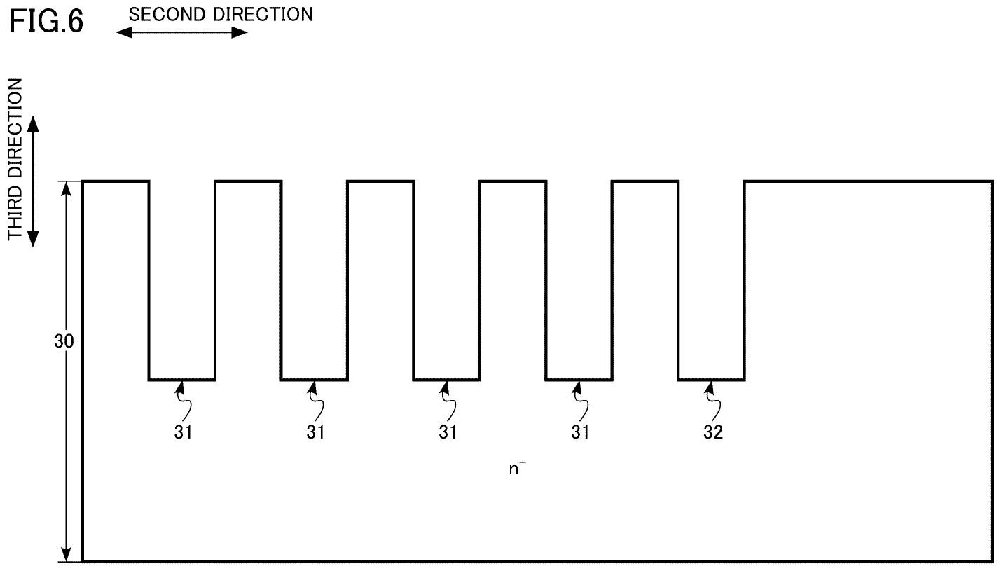

FIGS. 6, 7, 8, 9, 10, 11, and 12 are views for describing the semiconductor device manufacturing method according to the embodiment. FIGS. 6 to 12 are cross-sectional views corresponding to FIG. 2 of the embodiment.

First, the cell trench 31 and the termination trench 32 are formed in the semiconductor layer 30 of n-type by using a known process technique (FIG. 6). The cell trench 31 and the termination trench 32 are simultaneously formed. A part of the semiconductor layer 30 finally becomes the drift region 34.

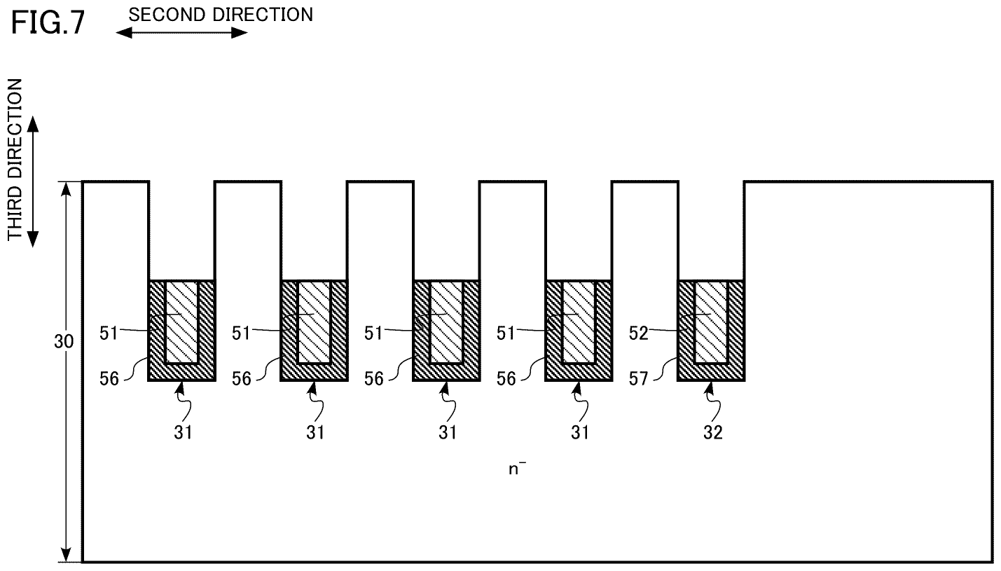

Next, the first field plate insulating layer 56 and the first field plate electrode 51 are formed in the cell trench 31 using a known process technique. In addition, the second field plate insulating layer 57 and the second field plate electrode 52 are formed in the termination trench 32 by using a known process technique (FIG. 7).

Next, a first silicon oxide film 70 is formed so as to fill a part of the cell trench 31 and the termination trench 32. The first silicon oxide film 70 is formed by, for example, a chemical vapor deposition method (CVD method). A part of the first silicon oxide film 70 finally becomes the first inter-electrode insulating layer 61, the second inter-electrode insulating layer 62, and the third gate insulating layer 48.

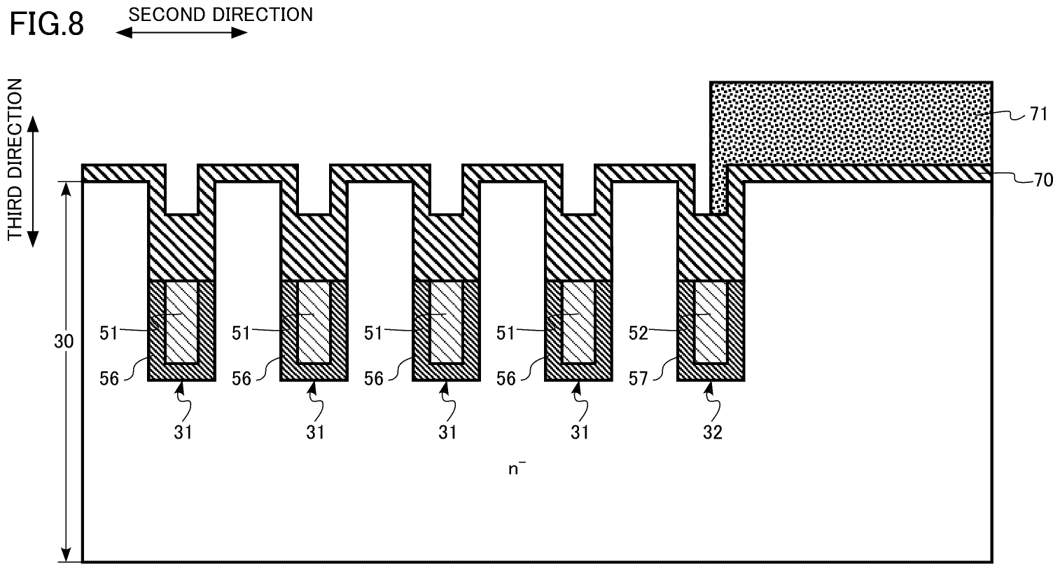

Next, a resist film 71 for patterning the first silicon oxide film 70 is formed on the first silicon oxide film 70 (FIG. 8). The resist film 71 covers a part of the first silicon oxide film 70 filling the termination trench 32 and exposes another part of the first silicon oxide film 70. In other words, an end portion of the resist film 71 is provided in the termination trench 32.

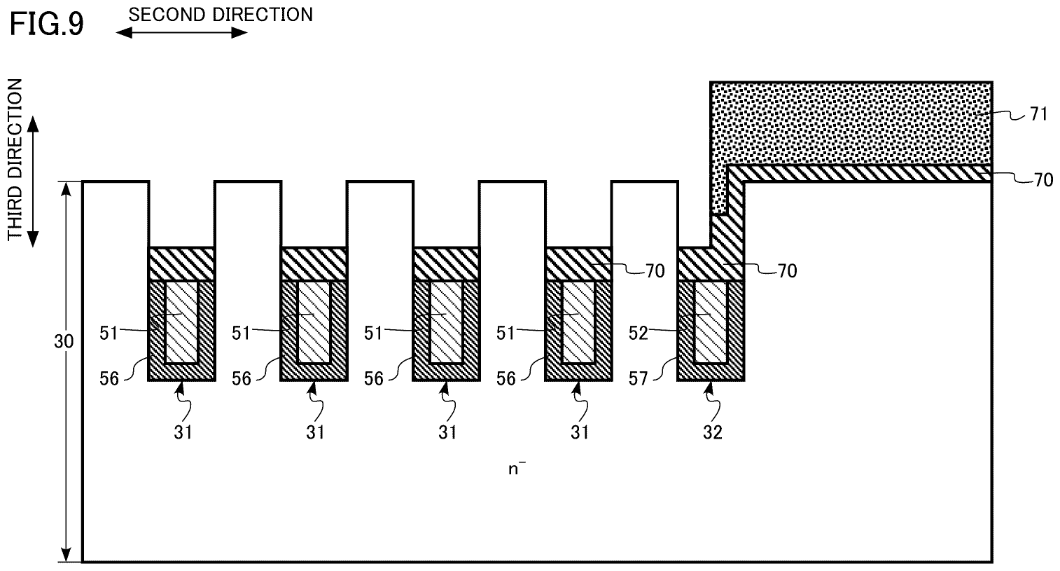

Next, a part of the first silicon oxide film 70 is removed using the resist film 71 as a mask (FIG. 9). A part of the first silicon oxide film 70 is removed using, for example, a wet etching method.

By removing a part of the first silicon oxide film 70, portions of the semiconductor layer 30 on both side faces of an upper portion of the cell trench 31 are exposed. In addition, the portion of the semiconductor layer 30 on the side face on the side adjacent to the cell trench 31 at the upper portion of the termination trench 32 is exposed. The side face on the side opposite to the cell trench 31 at the upper portion of the termination trench 32 remains covered with the first silicon oxide film 70. The first silicon oxide film 70 covering the side face on the side opposite to the cell trench 31 at the upper portion of the termination trench 32 finally becomes the third gate insulating layer 48.

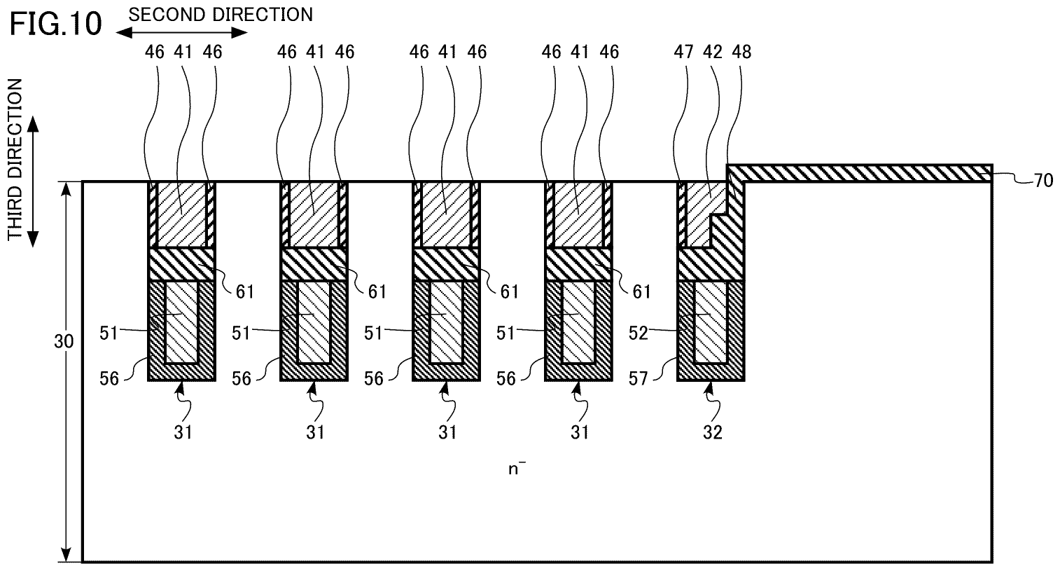

Next, the resist film 71 is removed. Next, the first gate electrode 41, the second gate electrode 42, the first gate insulating layer 46, and the second gate insulating layer 47 are formed using a known process technique (FIG. 10).

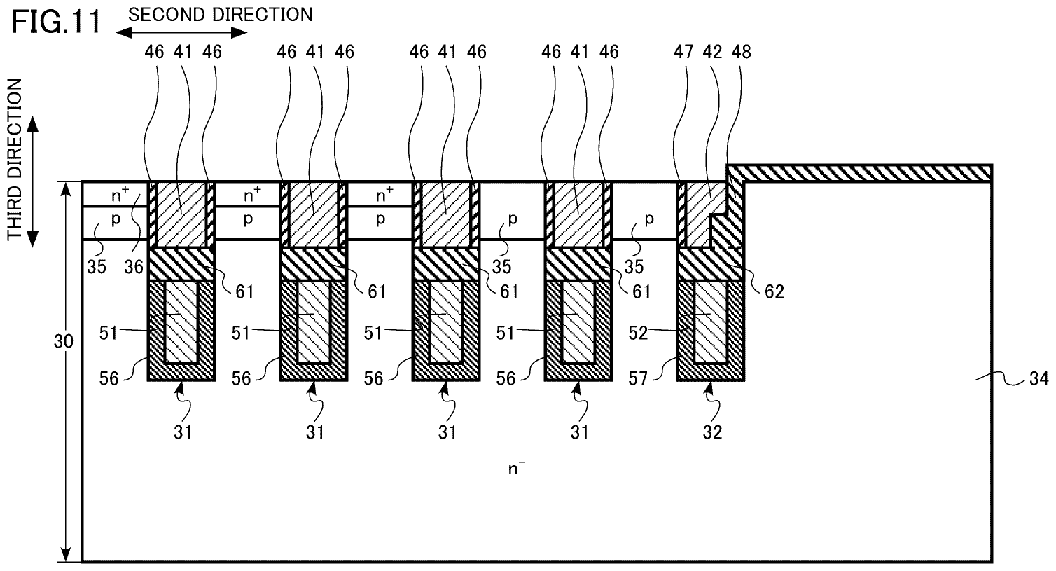

Next, the body region 35 of p type and the source region 36 of n+ type are formed using a known process technique (FIG. 11).

Next, a second silicon oxide film 72 is formed on the semiconductor layer 30. The second silicon oxide film 72 is formed by, for example, a CVD method. A part of the second silicon oxide film 72 finally becomes the interlayer insulating layer 65.

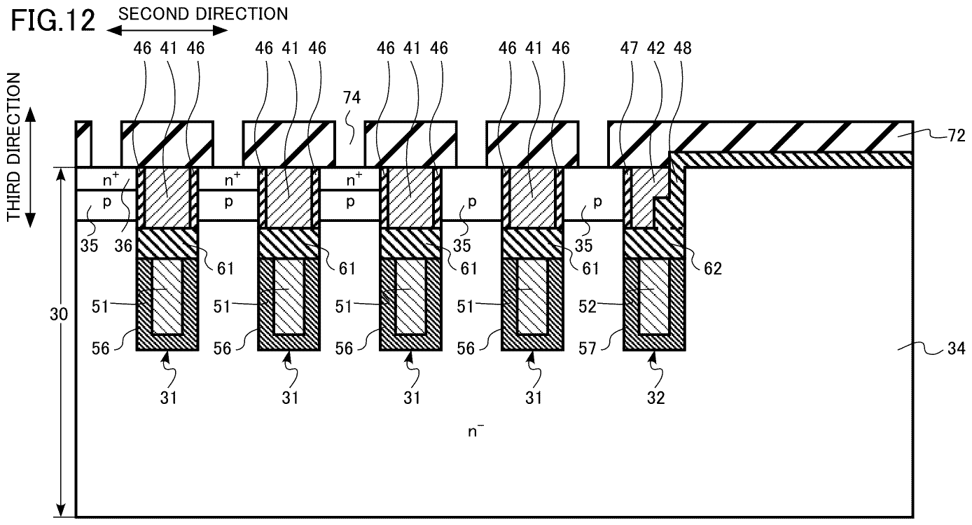

Next, an opening 74 reaching the surface of the semiconductor layer 30 is formed in the second silicon oxide film 72 (FIG. 12). The opening 74 is formed by using, for example, a lithography method and a reactive ion etching method (RIE method). For example, it is also possible to have a structure in which the semiconductor layer 30 at a bottom portion of the opening 74 is also etched, and the opening 74 penetrates through the source region 36.

Then, the opening 74 is filled with a metal film using a known process technique to form the source electrode 10. In addition, the drain region 33 and the drain electrode 20 are formed on the back surface side of the semiconductor layer 30 by using a known process technique.

The MOSFET 100 according to the embodiment illustrated in FIG. 2 is manufactured by the above semiconductor device manufacturing method.

Next, functions and effects of the semiconductor device according to the embodiment will be described.

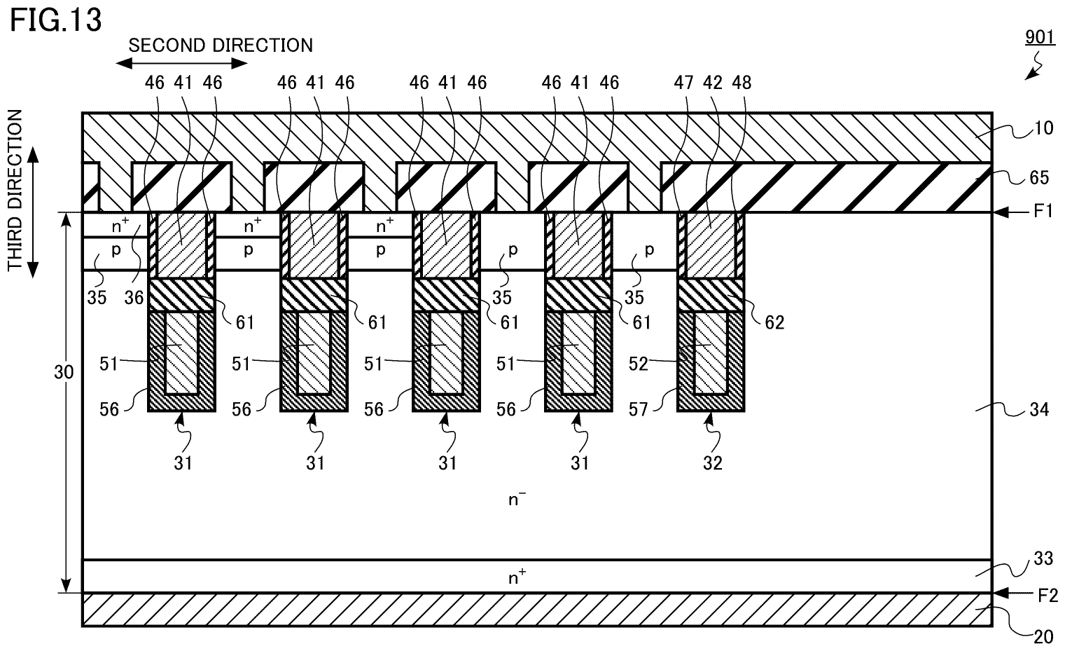

FIG. 13 is a schematic cross-sectional view of a part of a semiconductor device according to a first comparative embodiment. FIG. 13 is a view corresponding to FIG. 2 of the embodiment.

A MOSFET 901 according to the first comparative embodiment is different from the MOSFET 100 according to the embodiment in that a length of a second gate electrode 42 in a third direction is constant. The MOSFET 901 according to the first comparative embodiment is different from the MOSFET 100 according to the embodiment in that a thickness of a third gate insulating layer 48 is the same as a thickness of a second gate insulating layer 47.

In the MOSFET 901, electric field concentration occurs outside a termination trench 32 when the MOSFET 901 is turned off. Specifically, an electric field intensity applied to the third gate insulating layer 48 between a drift region 34 outside the termination trench 32 and the second gate electrode 42 increases. For this reason, dielectric breakdown of the third gate insulating layer 48 is likely to occur, and reliability of the gate insulating layer may be lowered.

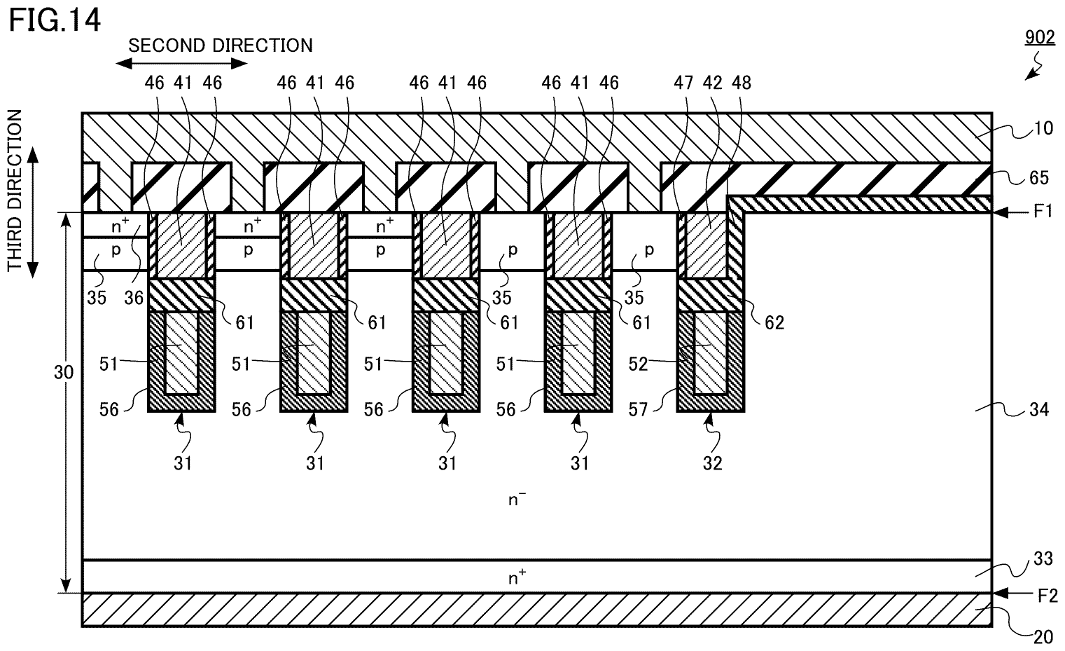

FIG. 14 is a schematic cross-sectional view of a part of a semiconductor device according to a second comparative embodiment. FIG. 14 is a view corresponding to FIG. 2 of the embodiment.

A MOSFET 902 according to the second comparative embodiment is different from the MOSFET 100 according to the embodiment in that a length of a second gate electrode 42 in a third direction is constant. The MOSFET 902 according to the second comparative embodiment is different from the MOSFET 901 according to the first comparative embodiment in that a thickness of a third gate insulating layer 48 is larger than a thickness of a second gate insulating layer 47.

In the MOSFET 902, since the thickness of the third gate insulating layer 48 is larger than the thickness of the second gate insulating layer 47, an electric field intensity applied to the third gate insulating layer 48 decreases when the MOSFET 902 is turned off. Therefore, reliability of the gate insulating layer is improved as compared with the MOSFET 901 according to the first comparative embodiment.

In the MOSFET 100 according to the embodiment, as illustrated in FIG. 4, the second length (L2 in FIG. 4) of the first portion of the second gate electrode 42 on the side adjacent to the cell trench 31 in the third direction is larger than the third length (L3 in FIG. 4) of the second portion of the second gate electrode 42 on the side opposite to the cell trench 31 in the third direction. In other words, the third length L3 is smaller than the second length L2.

Therefore, an area of the second gate electrode 42 facing the drift region 34 outside the termination trench 32 across the thin portion of the third gate insulating layer 48 is reduced. Therefore, a capacitance between the second gate electrode 42 of the MOSFET 100 and the drift region 34 outside the termination trench 32 is smaller than that of the MOSFET 902. Therefore, a gate-drain capacitance of the MOSFET 100 is reduced.

In addition, in the MOSFET 100, the area of the second gate electrode 42 facing the drift region 34 outside the termination trench 32 across the thin portion of the third gate insulating layer 48 is reduced. Therefore, reliability of the gate insulating layer is improved as compared with the MOSFET 902 according to the first comparative embodiment.

In addition, in the MOSFET 100 according to the embodiment, as illustrated in FIG. 4, the second distance (d2 in FIG. 4) between the second gate electrode 42 and the second field plate electrode 52 at the second position (P2 in FIG. 4) far from the cell trench 31 is larger than the first distance (d1 in FIG. 4) between the second gate electrode 42 and the second field plate electrode 52 at the first position (P1 in FIG. 4) close to the cell trench 31. Therefore, a capacitance between the second gate electrode 42 and the second field plate electrode 52 of the MOSFET 100 is smaller than that of the MOSFET 902. The second field plate electrode 52 is electrically connected to the source electrode 10. Therefore, a gate-source capacitance of the MOSFET 100 is reduced.

The MOSFET 100 according to the embodiment has a reduced gate capacitance as compared with the MOSFET 902 according to the second comparative embodiment. Therefore, for example, an operation speed of the MOSFET 100 is improved, and power consumption is reduced.

From the viewpoint of improving the reliability of the gate insulating layer, the third thickness t3 of the third gate insulating layer 48 is preferably 1.5 times or more, more preferably 2 times or more, and still more preferably 3 times or more the second thickness t2 of the second gate insulating layer 47.

From the viewpoint of reducing the gate capacitance and improving the reliability of the gate insulating layer, the second length L2 of the second gate electrode 42 is, for example, preferably 1.2 times or more, and more preferably 1.5 times or more the third length L3 of the second gate electrode 42.

From the viewpoint of reducing the gate capacitance, the second distance d2 between the second gate electrode 42 and the second field plate electrode 52 is preferably 1.2 times or more, more preferably 1.5 times or more the first distance d1.

From the viewpoint of reducing the gate capacitance and improving the reliability of the gate insulating layer, the first area S1 of the first region 42a illustrated in FIG. 5 is preferably 1.2 times or more, more preferably 1.5 times or more the second area of the second region 42b.

In the embodiment, a case where the semiconductor layer is single crystal silicon has been described as an example, but the semiconductor layer is not limited to single crystal silicon. For example, other single crystal semiconductors such as single crystal silicon carbide may be used.

In the embodiment, a case where the first conductivity type is n type and the second conductivity type is p type has been described as an example, but the first conductivity type may be p type and the second conductivity type may be n type.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode;
a semiconductor layer provided between the first electrode and the second electrode, having a first face facing the first electrode and a second face facing the second electrode, and including
a plurality of first trenches provided on a first face side of the semiconductor layer, extending in a first direction parallel to the first face, and disposed in a repeated pattern in a second direction parallel to the first face and perpendicular to the first direction,
a second trench provided on the first face side of the semiconductor layer, extending in the first direction, and disposed adjacent in the second direction to a first trench disposed at an endmost portion in the second direction among the first trenches,
a first semiconductor region of a first conductivity type electrically connected to the second electrode,
a second semiconductor region of a second conductivity type provided between the first semiconductor region and the first face and provided between two first trenches, and
a third semiconductor region of the first conductivity type provided between the second semiconductor region and the first face, provided between two first trenches, and electrically connected to the first electrode;
a first gate electrode provided in each of the first trenches and having a first length in a third direction perpendicular to the first direction and the second direction;
a first field plate electrode provided in each of the first trenches and provided between the first gate electrode and the second face;
a second gate electrode provided in the second trench, and a second length in the third direction of a portion of the second gate electrode on a side facing the first trenches being larger than a third length in the third direction of a portion of the second gate electrode on a side opposite to the first trenches;
a second field plate electrode provided in the second trench and provided between the second gate electrode and the second face;
a first gate insulating layer provided between the first gate electrode and the semiconductor layer and having a first thickness;
a first field plate insulating layer provided between the first field plate electrode and the semiconductor layer;
a first inter-electrode insulating layer provided between the first gate electrode and the first field plate electrode;
a second gate insulating layer provided between the second gate electrode and the semiconductor layer on the side facing the first trenches and having a second thickness;
a third gate insulating layer provided between the second gate electrode and the semiconductor layer on the side opposite to the first trenches and having a third thickness larger than the second thickness;
a second field plate insulating layer provided between the second field plate electrode and the semiconductor layer; and
a second inter-electrode insulating layer provided between the second gate electrode and the second field plate electrode.

2. The semiconductor device according to claim 1, wherein the second length is 1.2 times or more the third length.

3. The semiconductor device according to claim 1, wherein a face of the second gate electrode on a second face side has a step.

4. The semiconductor device according to claim 1, wherein the second length is 0.9 times or more and 1.1 times or less the first length.

5. The semiconductor device according to claim 1, wherein the third thickness is 1.5 times or more the second thickness.

6. The semiconductor device according to claim 1, wherein the second thickness is 0.9 times or more and 1.1 times or less the first thickness.

7. The semiconductor device according to claim 1, wherein
a first distance between the second gate electrode and the second field plate electrode in the third direction at a first position is smaller than a second distance between the second gate electrode and the second field plate electrode in the third direction at a second position farther from the first trenches than the first position in the second direction.

8. The semiconductor device according to claim 7, wherein the second distance is 1.2 times or more the first distance.

9. The semiconductor device according to claim 1, wherein a width of the second trench in the second direction is 0.9 times or more and 1.1 times or less a width of the first trench in the second direction.

10. The semiconductor device according to claim 1, wherein in a cross section parallel to the second direction and the third direction, in a case where the second direction is defined as a left-right direction, a shape of the second gate electrode is asymmetrical in the left-right direction.

11. The semiconductor device according to claim 1, wherein in a cross section parallel to the second direction and the third direction, in a case where the second gate electrode is virtually divided into a first region on the side facing the first trenches and a second region on the side opposite to the first trenches by a second line segment extending in the third direction and passing through a midpoint of a first line segment passing through a position where the second gate electrode has a maximum width in the second direction and drawn in the second direction in the second gate electrode, a first area of the first region is larger than a second area of the second region.

12. The semiconductor device according to claim 11, wherein the first area is 1.2 times or more the second area.
